(19) United States
(12) Patent Application Publication
(10) Pub. No.: US 2024/0203799 A1
(43) Pub. Date: Jun. 20, 2024

(54) INTEGRATED CIRCUIT (IC) FABRICATED IN A HIGH MIX ENVIRONMENT

(71) Applicant: TEXAS INSTRUMENTS INCORPORATED, Dallas, TX (US)

(72) Inventors: Vinod Anumareddy, Sandy, UT (US); Joshua Winger, West Jordan, UT (US)

(21) Appl. No.: 18/192,849

(22) Filed: Mar. 30, 2023

Related U.S. Application Data
(60) Provisional application No. 63/433,807, filed on Dec. 20, 2022.

(51) Int. Cl. H01L 21/66; H01L 21/67; H01L 21/677

(52) U.S. Cl. CPC H01L 22/26; H01L 21/67253; H01L 21/67276; H01L 21/67781; H01L 22/12

(57) ABSTRACT

An IC manufacturing system including a transition analysis engine configured to monitor inline and EOL response metrics and determine impact levels of one or more transitions that may be encountered at respective process stages of a fabrication facility. Inline response metrics data and transition data may be monitored for one or more process stages in addition to EOL response metrics relating to pluralities of semiconductor wafers, wherein the variance of the monitored data may be correlated to one or more transitions.

### CROSS-REFERENCE TO RELATED APPLICATIONS

This non-provisional application claims priority based upon U.S. provisional Application No. 63/433,807, filed Dec. 20, 2022, which is hereby incorporated by reference in its entirety.

### FIELD OF THE DISCLOSURE

Disclosed implementations relate generally to the field of semiconductor manufacturing.

### BACKGROUND

Within the semiconductor industry, there is a constant demand for integrated circuits (ICs) that exhibit higher performance at a lower cost. In order to design and manufacture high performance ICs cost-effectively, several parameters associated with the products flowing through a manufacturing process, e.g., process wafers, need to be monitored and carefully controlled. Increasing complexity of manufacturing and the need to correct issues in real time requires that actionable information regarding the various process steps of a process flow is readily available regardless of the type of tooling and process flows deployed in a facility.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Some examples of the present disclosure are directed to an IC manufacturing system including a transition analysis engine configured to monitor inline and end-of-line (EOL) response metrics and determine impact levels of one or more transitions that may be encountered at a respective process stage of a fabrication facility. Various types of inline response metrics data and transition data may be monitored for one or more process stages in addition to EOL response metrics relating to pluralities of semiconductor wafers. Some examples may be configured to analyze observed variances of the monitored data in order to determine whether they may be correlated to one or more transitions.

In one example, a method of fabricating an IC is disclosed. The method may include processing a plurality of semiconductor wafers in a fabrication flow having a sequence of process steps including a targeted process step, wherein the targeted process step may comprise an operation performed at a process tool using a first process recipe with respect to a material layer over the semiconductor wafers. A response metric variable may be measured for the semiconductor wafers, wherein the response metric variable may relate to a parameter associated with the semiconductor wafers. A first average of the response metric variable may be obtained for a first subset of the plurality of semiconductor wafers and a second average of the response metric variable may be obtained for a second subset of the plurality of semiconductor wafers. On the condition that a difference between the first and second averages is statistically significant, e.g., attributable to a transitional condition with respect to the targeted process step, the method may be configured to adjust one or more process parameters of the targeted process step. In an example implementation, the method may comprise processing a subsequent semiconductor wafer at the targeted process step containing the IC at an intermediate stage of formation, wherein the subsequent semiconductor wafer may be of the same technology node as the plurality of semiconductor wafers.

In one example, a method of fabricating an IC is disclosed wherein the method may include determining yield data, e.g., on a wafer-by-wafer basis, for a plurality of wafer lots processed through a fabrication flow having a sequence of process steps including a targeted process step. Depending on implementation, the targeted process step may comprise an operation performed at a process tool using a first process recipe with respect to a material layer over a plurality of semiconductor wafers in a wafer lot. A first average of a yield variable may be obtained from a first subset of each respective wafer lot. A second average of the yield variable may be obtained from a second subset of each respective wafer lot. On the condition that a difference between the first and second averages is statistically significant, e.g., attributable to a transitional condition with respect to the targeted process step, the method may be configured to adjust one or more process parameters of the targeted process step. In an example implementation, the method may comprise processing a subsequent wafer lot including a semiconductor wafer at the targeted process step containing the IC at an intermediate stage of formation, wherein the subsequent wafer lot containing the semiconductor wafer may be of the same technology node as the plurality of wafer lots immediately preceding the subsequent wafer lot.

In another example, an IC is disclosed, which may comprise, inter alia, a material layer formed over a semiconductor wafer at a targeted process step of a fabrication flow, the semiconductor wafer forming a substrate for the IC. In one arrangement, the material layer may be reworked responsive to determining that a difference between a first average of a response metric variable and a second average of the response metric variable are statistically significant and attributable to a transitional condition with respect to the targeted process step performed by a process tool using a first process recipe.

In a further example, an apparatus including an inline/EOL metrics station based on a computer platform is disclosed, wherein the computer platform may be configured to execute a transition analysis engine, e.g., a script-based engine, comprising a plurality of program instructions for performing one or more methods set forth herein.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1A depicts a representative high mix manufacturing system configured to fabricate semiconductor wafers in a plurality of process flows wherein response metrics may be monitored and analyzed according to some examples of the present disclosure;

FIG. 1B illustrates some transitional conditions in a representative high mix manufacturing system that may affect response metrics in an example of the present disclosure;

FIG. 2 depicts a portion of a high mix manufacturing system wherein a transition analysis engine may be implemented for identifying response metrics variability due to transitional conditions in accordance with some examples;

FIG. 3 depicts a scheme for deploying transition analytics with respect to one or more inline and/or end-of-line (EOL) response metrics in a semiconductor fabrication flow;

FIGS. 4A and 4B depict example response metrics relationships relative to a wafer slot or run order sequence at a targeted process step that may be undergoing a transitional condition;

FIG. 5 depicts a slot delta metric relative to a response metric variable obtained based on extremal (sub)sampling of wafer lots or process runs for isolating response metric variability due to transitional conditions according to some examples of the present disclosure; and

FIGS. 6A and 6B are flowcharts of an IC fabrication method according to some examples of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, it will be appreciated by one skilled in the art that the examples of the present disclosure may be practiced without such specific components, structures or subsystems, etc.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. “Directly connected” may be used to convey that two or more physical features touch, or share an interface between each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of a semiconductor IC device manufacturing environment.

For purposes of the present disclosure, a high mix IC device manufacturing environment may be a production facility or a foundry that may be configured to run multiple product lines, types, designs, etc., using a variety of process recipes organized into one or more fabrication flows in accordance with known or heretofore unknown semiconductor technologies executed on a substantially common set of processing tools. Depending on implementation, example semiconductor technologies may comprise bipolar junction transistor technologies, metal oxide semiconductor (MOS) technologies, complementary metal oxide semiconductor (CMOS) technologies, double-diffused metal oxide semiconductor (DMOS) technologies, etc., including analog and/or digital device designs. In some examples, a combination of semiconductor technologies may be implemented, wherein different technologies suitable for respective types of product design may be integrated within the same chip or IC device, e.g., BiCMOS (a bipolar-CMOS combination technology where bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Relatedly, some example high mix environments may also be configured to fabricate various types of IC devices using multiple technology nodes, which may also be referred to as process nodes or simply “nodes”, wherein a technology node may refer to a specific semiconductor manufacturing process and its design rules. Depending on the manufacturing facility, different nodes may correspond to different circuit generations and architectures. Generally, the smaller the technology node, the smaller the feature size, thereby resulting in smaller transistors that are typically faster and more power-efficient in some implementations. Further, an example technology node may refer to a transistor's feature sizes such as, e.g., gate lengths, a metal layer's half-pitch, etc. Accordingly, example technology nodes in some representative IC device manufacturing environments may comprise 22 nm nodes, 16 nm nodes, 14 nm nodes, 10 nm nodes, etc., and/or any combination thereof. Still further, a product mix of some example foundries may comprise IC devices that may be deployed in myriad applications such as, e.g., audio/video applications, telecommunications applications, automotive applications, digital signal processing applications, optical networking applications, digital control applications, Internet-of-Things (IOT) applications, and the like.

Depending on implementation, a semiconductor IC device manufacturing flow may comprise a number of processing stages involving wafer fabrication and backend operations such as e.g., front-end-of-line (FEOL) operations, middle-of-line (MOL) operations, and back-end-of-line (BEOL) operations, which may be followed by “post-fab” processing stages that may include wafer test, backgrinding, die separation, die test and IC packaging for shipping. Regardless of the process node or technology used and/or the product mix(es) involved, the FEOL/MOL/BEOL stages of a flow may comprise one or more thin-film and/or thick-film processing/deposition stages, one or more photolithography stages, implant stages, thermal treatment stages, etching stages, chemical-mechanical polishing (CMP) stages, metallization/interconnect stages, etc., among others, wherein a plurality of semiconductor wafers may be processed on a wafer-by wafer basis, on a lot-by-lot basis, or in a batch mode involving a number of wafer lots or process runs, using appropriate tooling and equipment. At an example process step, a material layer of the semiconductor wafer may be processed so as to alter one or more physical and/or electrical characteristics of the material layer. In some examples, a process step may add to or subtract from a material layer, e.g., deposition of conductive layers, nonconductive or dielectric layers, etching or polishing of layers, and the like. In general, the tooling equipment used in performing various process steps of any FEOL/MOL/BEOL stages of a manufacturing flow may be operated and monitored under suitable controls, which may be effectuated manually and/or automatically, in order that appropriate information regarding the process parameters, operational settings, operator interaction variables, etc. may be gathered and analyzed for effectuating suitable process control. Similarly, the equipment deployed at various post-fab stages may also be operated and monitored, whereby data may be gathered and analyzed for facilitating appropriate process control.

Given the highly serialized nature of wafer processing in a foundry, a variety of inline measurement and testing equipment may be deployed at and/or in between various processing steps in order to ensure that appropriate process variables, design rules, electrical parameters, etc., are within applicable control limits. For example, thin film metrology based on ellipsometry or reflectometry may be used in an example fabrication flow to monitor the thickness of gate oxide, as well as the thickness, refractive index and extinction coefficient of photoresist and other coatings that may be applied to the semiconductor wafers at various stages. In some examples, inline wafer defect detection systems may be deployed to monitor both micro- and macro-defects which may comprise and/or be caused by, e.g., non-uniform exposure, solvent drips, material residues after clean, striations, misplaced scribe or array positioning, resist bubbles, scratches, particulate matter, off-center resist dispense, peeling, etc. In addition to inline measurement and testing, the semiconductor wafers may be tested after BEOL processing, e.g., before die preparation and singulation, for compliance with various electrical parameters, quality/reliability requirements, as well as for characterizing wafer yield data as well as functional binning data, where yield may be defined as the percentage of functional die per wafer (DPW). For purposes of the present disclosure, data relating to at least a portion of the inline measurement variables and/or EOL variables illustrated above may be referred to as response metrics data.

In some arrangements, one or more statistical process control (SPC) or statistical quality control (SQC) methodologies may be deployed in a manufacturing facility in order to monitor and control the deployed fabrication flows both at inline stages as well as at end-of-line (EOL) stages. In some arrangements, example SPC/SQC methodologies may be deployed at a targeted process step of a flow so as to help ensure that the targeted process step is operating efficiently and within control, thereby producing more conforming products with less waste in the downstream flow (e.g., rework, scrap or other disposition). For example, process wafers, wafer lots, groups of wafer lots, etc., collectively referred to as sampling units, may be monitored to ascertain that applicable control limits and/or specification thresholds are satisfied with respect to one or more measurement parameters and/or variables relevant to the sampling units processed at the targeted stage. In some arrangements, example SPC/SQC methodologies may include generating run charts, control charts, etc., as well as performing process capability analyses and/or conducting statistically designed experiments, and the like, wherein inline measurement data, EOL yield and quality data as well as equipment settings data may be produced, processed, stored, and deployed for purposes of yield management, monitoring and quality control.

It should be appreciated that increasing product lines/mixes and technology nodes at a foundry may often be accompanied by an increase in the variety of process recipes and flows running on a substantially common set of tools deployed at the foundry, which can give rise to a significant increase in multiple types of transitional conditions or states in a manufacturing environment, wherein a transitional condition or state may refer to a transition of a process-related tool or step from a first state consistent with a first manufacturing flow to a second state consistent with a second manufacturing flow in some arrangements. In additional and/or alternative arrangements, a transitional condition may refer to a tool- and/or process-related transition within the same fabrication flow. Whereas some transitions can be benign, others may negatively impact downstream processing, potentially leading to yield, quality and reliability issues at the EOL stage, especially in view of the sequential nature of wafer processing as illustrated above. Troubleshooting out-of-specification and/or out-of-control inline measurement data as well as reduced yields or compromised quality/reliability within the context of—and relative to—various transitional states of a high mix manufacturing environment can be particularly challenging as the transitions often go unnoticed and/or unresolved in a timely fashion. Further, as pluralities of wafers or wafer lots are processed in groups or batches back-to-back at different stages, delays in identifying and resolving transitional issues can have a ripple effect in the downstream flow, thereby undermining a foundry's process control and yield management goals.

Examples described herein recognize the foregoing challenges and contingencies and accordingly provide a transition analysis scheme configured to identify potential transitional states in a manufacturing environment that may contribute to inline and EOL metrics variability in a significant manner. Some examples may be configured to generate suitable inline and/or EOL alarm signals in response to identifying one or more actionable transition states at different stages in a process flow wherein appropriate corrective action(s) may be undertaken. In some arrangements, applicable response action plans may be triggered, automatically and/or manually, e.g., with respect to adjusting processing parameters of one or more process steps and/or re-seasoning or reconditioning of the tooling equipment. In some arrangements, an example implementation may be configured to identify actionable transitional states automatically across a large number of processing steps of a flow, wherein various types of response metrics data (e.g., inline and EOL metrics data) may be monitored and statistically analyzed for identifying specific transitional states or conditionalities that may affect a product line at one or more levels of sampling or subsampling, e.g., at wafer level, lot level or frame level (e.g., a process run comprising a group of wafer lots). It should be appreciated that while the examples of the present disclosure may be expected to provide some tangible improvements over baseline inline monitoring and yield management tools, no particular result is a requirement unless explicitly recited in a particular claim appended hereto.

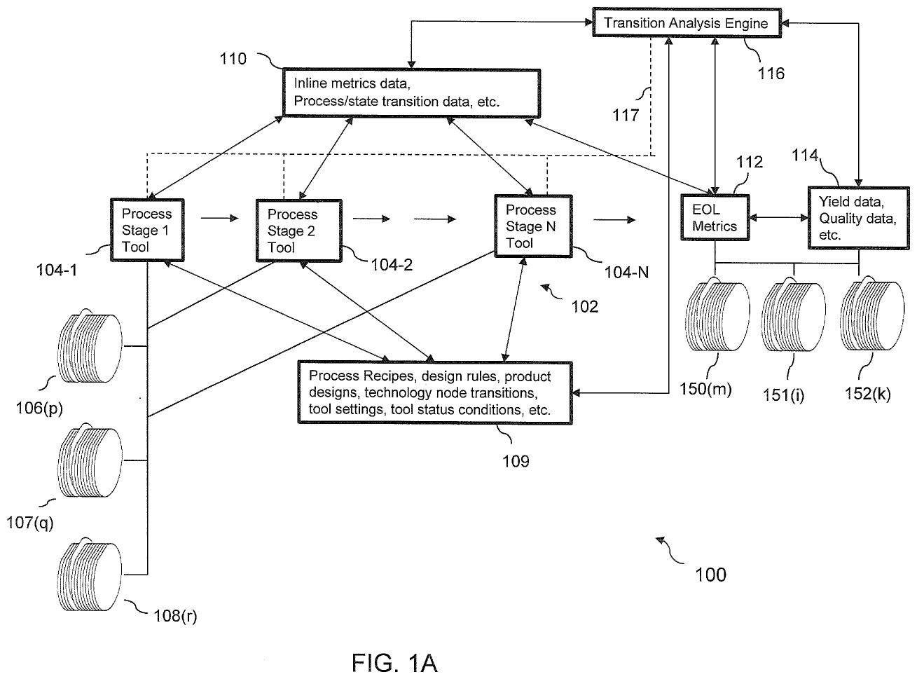

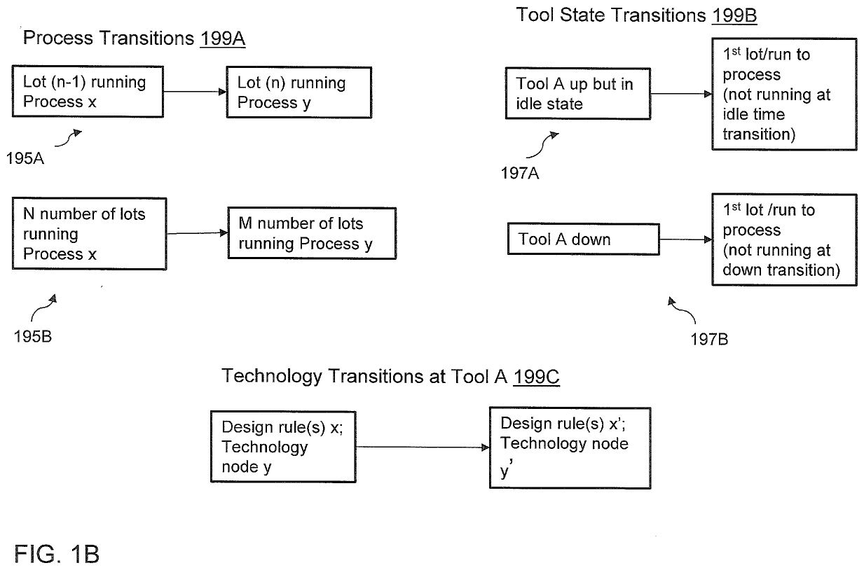

Turning to Figures, FIG. 1A depicts a representative high mix manufacturing system 100 configured to fabricate semiconductor wafers in a plurality of process flows wherein response metrics may be monitored and analyzed according to some examples of the present disclosure. By way of illustration, the manufacturing system 100 may comprise a plurality of process stages or steps 104-1 to 104-N that may be run on corresponding tooling stations associated therewith, respectively, which may be co-located, distributed or otherwise disposed in one or more foundry facilities, collectively referred to a fabrication plant 102. In some arrangements, the process stages 104-1 to 104-N, which may comprise FEOL, MOL, and/or BEOL portions of various process flows, respectively, may be configured or reconfigured depending on the technology nodes and product mix combinations supported by the manufacturing system 100. Example processing stages or techniques may comprise without limitation, wafer cleaning, surface passivation, photolithography, ion implantation, dry etching (including, e.g., plasma etching, reactive-ion etching, atomic layer etching, etc.), wet etching, deposition (including, e.g., chemical vapor deposition, physical vapor deposition, atomic layer deposition, molecular beam epitaxy, etc.), plasma ashing, thermal treatments including rapid thermal annealing, metallization, chemical-mechanical polishing, etc. It should be apparent that the foregoing list does not necessarily imply a specific order, nor that all listed processing stages or techniques are executed during manufacture of a particular IC device or product. In general, different process flows run in the manufacturing system 100 may each have a respective order of the processing stages, wherein semiconductor wafers (also referred to as process wafers, semiconductor process wafers, or simply wafers) for forming or containing IC devices at different stages of formation may be processed using applicable process recipes on a wafer-by-wafer basis, lot-by-lot basis, or as batch of wafer lots, by respective tooling stations as noted previously. By way of illustration, wafer lot groups 106(p), 107(q), 108(r) are each examples of pluralities of wafers or wafer lots, wherein the wafers may be of different sizes, that may be processed using at least a portion of the illustrated process stages 104-1 to 104-N for fabricating different types of IC devices or products.

Depending on the combination(s) of technology nodes and product mixes supported by the fabrication plant 102, example process stages 104-1 to 104-N may be effectuated based on corresponding process recipes, tool settings, operational parameters, etc., which may be changed dynamically as needed in order to accommodate the processing of wafers with different types of IC devices. Further, at least some tools deployed at respective process stages may undergo various states, e.g., idling, offline (e.g., down), online (e.g., up and running), test/pilot mode, production mode, trial mode, development mode, post/pre-conditioning, etc. For purposes of the present disclosure, reference number 109 collectively refers to at least a portion of various manufacturing conditionalities relating to process recipes, tool settings and states, etc. that may undergo transitional states due to changes in technology nodes, product mixes, design rules, and the like, and/or otherwise, which may be effectuated at respective process stages 104-1 to 104-N.

In some arrangements, one or more product characterization stations 110 may be deployed with respect to monitoring various parameters and variables, referred to as inline metrics, associated with different product wafers as they are processed through different process stages 104-1 to 104-N. Depending on implementation, example inline metrics may comprise data relating to critical dimensions (CDs), gate lengths and overlays, film thicknesses and uniformities, macro- and micro-defect counts, etc., as well as electrical properties such as sheet resistance and the like. In some arrangements, example product characterization stations 110 may be configured as inline metrology stations and/or inline wafer defect detection stations, which may be further configured to monitor, receive and/or otherwise obtain data relating to various transitional states or conditionalities that may be dynamically occurring at respective process stages. Further, one or more EOL metrics stations 112 may also be provided, which may be configured to monitor, receive or otherwise obtain EOL metrics data 114 relating to yield, functional/electrical parametrics, quality and reliability performance, etc., with respect to pluralities of wafer lots, e.g., wafer lot groups 150(m), 151(i), 152(k), processed through the BEOL stages of respective process flows. In some arrangements, example EOL metrics stations 112 may be configured as or associated with wafer probe stations operable to test wafers for functional defects by applying specific test patterns depending on the functionalities of the IC devices formed in the wafers. In some arrangements, EOL metrics stations 112 may also be configured to monitor, receive and/or otherwise obtain transitional state data associated with respective upstream process stages 104-1 to 104-N, either directly therefrom, or via one or more inline product characterization stations 110, or in combination thereof.

For purposes of the present disclosure, response metrics (e.g., inline metrics and/or EOL metrics) may be considered as dependent variables that may exhibit variance due to a variety of sources of variation including, e.g., variation in process margins, transitional states at different process stages, and the like. Depending on the type of response metrics measured, an example response metric variable may take on values comprising quantitative data, qualitative data, ordinal or categorical data, cardinal data, continuous data, or discrete data. As will be set forth in detail further below, a transition analysis engine 116 may be configured to analyze observed variations in respective response metrics variables based on appropriate statistical techniques. In some examples, the transition analysis engine 116 may be further configured to determine, detect or otherwise isolate potential transitional states associated with one or more process stages that may be identified as contributing factors with respect to the variability of the response metrics in a significant manner so as to engender potentially actionable response triggers in a product flow of the manufacturing environment 100. Depending on implementation, some actionable response triggers may be configured to operate as response signals 117 provided to one or more upstream process stages 104-1 to 104-N that have (or might have had) transitional states determined to contribute to the response metric variability in order to effectuate suitable adjustments with respect to one or more process parameters of the process stage, tool settings, and the like. In some arrangements, an implementation of the transition analysis engine 116 may be deployed as a real-time inline SPC/SQC station, e.g., in conjunction with a product characterization station 110, for facilitating dynamic interdiction of a process flow where a transitional condition is determined to cause a significant variation in an observed inline response metric variable. Further, an implementation of the transition analysis engine 116 may be deployed as an EOL yield management or enhancement tool configured to identify sources of yield loss or reduction not only due to normal process variation, process corners, particulate defects, etc., but also because of various transitional conditionalities encountered at different process stages in the high mix manufacturing environment 100.

FIG. 1B illustrates some transitional conditions in a representative high mix manufacturing system that may affect response metrics in an example of the present disclosure. Without limitation, example process transitions 199A illustrate two types of transitions: a lot-to-lot process transition 195A wherein a process (e.g., recipe [x]) running at a tool for a wafer lot transitions to a different process (e.g., recipe [y]) running at that tool for a next wafer lot; and a frame-to-frame process transition 195B wherein a process (e.g., recipe [x]) running at a tool for a batch (N) of wafer lots transitions to a different process (e.g., recipe [y]) running at that tool for a next group or batch (M) wafer lots. In some examples, the lots before and after the illustrative process recipe transitions may comprise wafer lots containing IC devices (e.g., at an intermediate stage of formation) of a same technology node although it is not a requirement. In similar fashion, example tool state transitions 199B illustrate a scenario 197A where a tool that is up but in idle state transitions to a run state for processing a first wafer lot or a batch of wafer lots after the transition. Tool state transition scenario 197B illustrates a conditionality where a tool is down (e.g., offline due to power outage, service maintenance, etc.) is brought up to a run state wherein one or more wafer lots are processed. Example technology node transitions 199C are illustrative of a conditionality at a particular tool where a set of design rules [x] or more broadly, a technology node [y] used for processing one or more wafer lots at the tool are changed to another set of design rules [x′] and/or technology node [y′] for processing next one or several wafer lots at that tool. Skilled artisans will recognize that the foregoing list of transitional conditions are purely illustrative and there can be various other types of transitional conditions in an example high mix manufacturing system. Furthermore, an example high mix manufacturing system having a plurality of process stages, e.g., process stages 104-1 to 104-N shown in FIG. 1A, may encounter different types of transitions at respective process stages, where some of the transitions may impact inline and/or EOL response metrics while others may not (e.g., benign transitions).

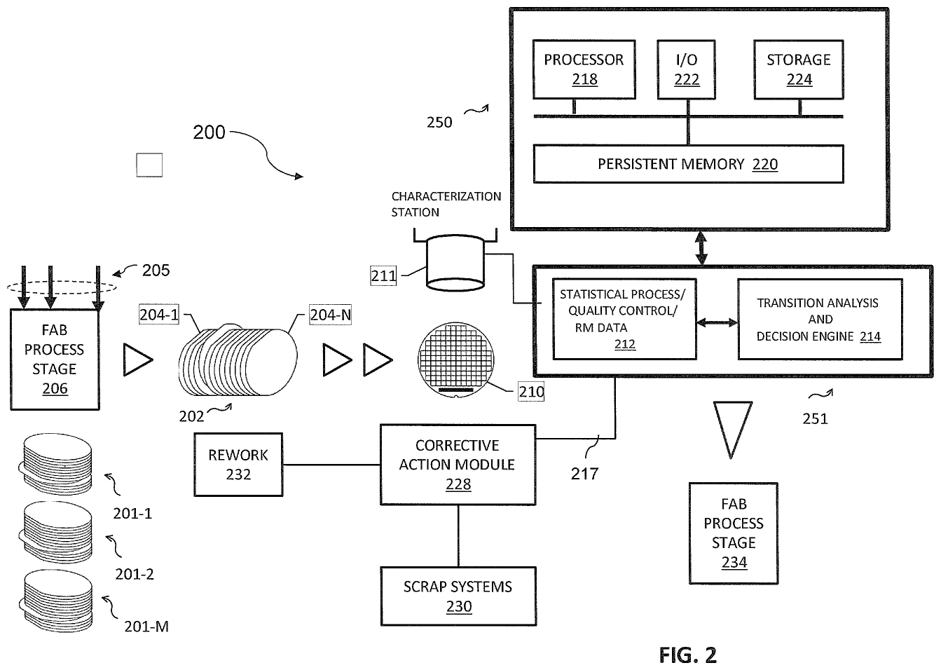

FIG. 2 depicts a portion 200 of a high mix manufacturing system wherein a transition analysis engine may be implemented for identifying response metrics variability due to transitional conditions in accordance with some examples. Depending on implementation, portion 200 may include a targeted FEOL/BEOL process step 206 configured to process pluralities of wafer lots 201-1 to 201-M using a tool that may be loaded with the wafers, lot-by-lot, or chamber-by-chamber where multiple lots are loaded as a frame run, and in a given slot order sequence that identifies a run sequence of loading of the wafers from a lot into the tool. As noted above, the wafer lots 201-1 to 201-M may comprise wafers of same or different technology nodes, wherein the targeted process step 206 may encounter a variety of transitional conditions 205 during processing of the wafer lots 201-1 to 201-M. In some arrangements, response metrics data may be collected by a characterization station 211, e.g., on a wafer-by-wafer basis, lot-by-lot basis and/or frame-by-frame basis, depending on relevant sampling or subsampling schemes implemented with respect to the targeted process step. As illustrated, a current wafer lot 202 comprising wafers 204-1 to 204-N may be measured or otherwise characterized by the characterization station 211 for obtaining response metrics data for each wafer or selected wafer 210 of the wafer lot 202. Data relating to a measured response metrics variable may be aggregated and/or averaged over an entire wafer or a wafer lot or some other sampling unit. Depending on implementation, the characterization station 211 may be operable with a local or a remote node 251 including a transition analysis and decision engine 214 for analyzing the variability of the measured response metrics data, e.g., inline metrics data and/or EOL metrics data, with respect to one or multiple transitions 205 at the process stage 206. In some arrangements, node 251 may also include a statistical process/quality control module 212 configured to generate, maintain and store various run charts, control charts, process capability indices and distributions, as well as measurement history data relative to one or more response metrics that may be measured by the characterization station 211.

Regardless of whether node 251 is integrated with the inline/EOL characterization station 211, node 251 may be implemented in any known or heretofore unknown hardware/software/firmware architectures on a suitable computing platform 250, e.g., a workstation or a server, having one or more processors 218 coupled to a persistent memory 220 containing machine-executable code or program instructions, which may be configured to effectuate statistical techniques for assessing response metrics variability relative to the transitional condition data 205 associated with the targeted process step 206. Appropriate input/output (I/O) modules 222 and one or more storage units 224 may be provided as part of the computing platform 250 depending on implementation. In some arrangements, depending on whether a measured response metrics variable is not compliant with applicable controls, thresholds, or other specifications, and/or whether a transition condition at the targeted process step 206 is statistically significantly related to the variability of the measured response metrics variable, appropriate corrective actions may be executed by a corrective action module 228 responsive to suitable control signals 217 generated by the node 251. Example corrective action plans may involve identifying the wafers for scrapping or reworking as respectively indicated by blocks 230 and 232, depending on fabrication flow management strategy including cost-benefit considerations as to wafer scrap and reworking guidelines as well as the institutional knowledge and domain expertise relating to the targeted process stage. Where the process stage 206 comprises an intermediary stage in the process flow, wafer lots 201-1 to 201-N may proceed to a next stage or step 234 after being appropriately characterized, e.g., in the event that the wafers of the current process run are within applicable controls and specifications (after reworking where needed).

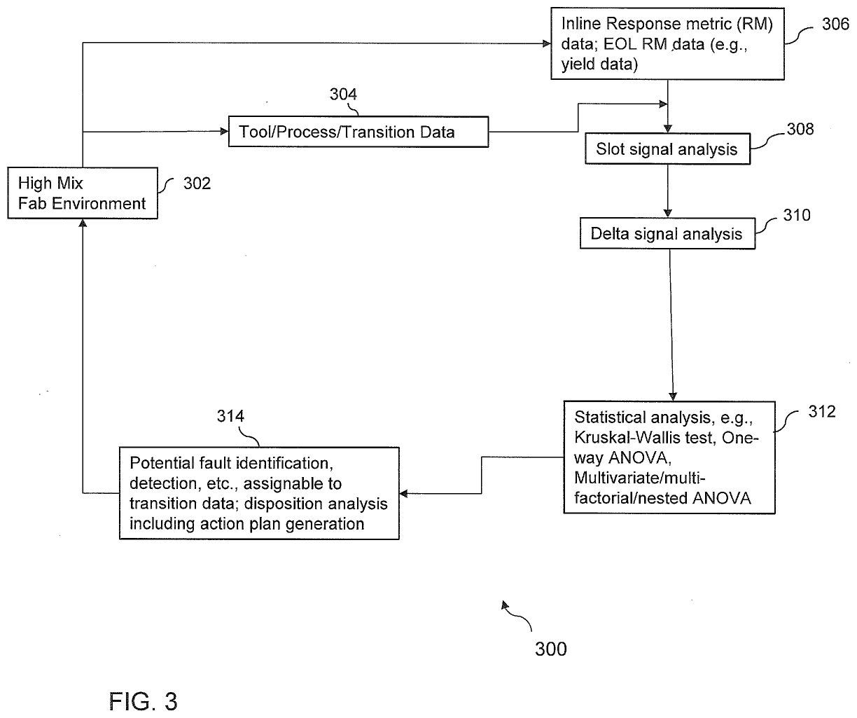

FIG. 3 depicts a scheme for deploying transition analytics with respect to one or more inline and/or EOL response metrics in a semiconductor fabrication flow according to some examples. At block 304, data relating to various types of transitional conditionalities associated one or more process stages of a high mix environment 302 may be obtained, e.g., continuously, periodically, or when a state transition is detected with respect to a process recipe, tool, technology node, and the like, at a process stage. In similar fashion, various pieces of data relating to one or more response metrics variables may be obtained, as set forth at block 306. In some example arrangements, a slot signal analysis or process order signal analysis may be performed at block 308 that monitors trends in a response metrics variable relative to a slot order sequence. As will be set forth further below, an increasing trend or a decreasing trend in a response metric variable over a run order, e.g., the loading/processing sequence of wafers in a tool at a particular process step, may be interrogated with the transitional conditionality data associated with the process step for identifying any correlation between the two sets of data. Where there is a state transition, e.g., in a process recipe or a tool state, and the wafers are processed subsequently using the “transitioned” tool/process recipe, there may be a lag time before the targeted process “settles” to a process equilibrium capable of generating a series of response metric values that are consistent across all the wafers in a lot or a frame. Accordingly, a series of increasing or decreasing values across a relevant sampling horizon may be considered a process transient signal that may be correlated to the transitional condition in a post hoc analysis. Some examples may also involve machine learning (ML) or other artificial intelligence (AI) techniques augmented with appropriate training for analyzing slot signals to generate predictive correlations with increased reliability.

In some examples, a delta signal analysis may be provided (block 310) in addition to (or independent of) slot signal analysis, wherein a delta or difference between the average (μ1) of a response metric variable for a first subset of a plurality of wafers (or a relevant sample of a plurality of wafer lots) and the average (μ2) of the response metric variable for a second subset of the plurality of wafers (or a relevant sample of the plurality of wafer lots) may be determined. Such delta signals may be compared and analyzed with respect to the transitional conditionalities using various statistical techniques such as, e.g., parametric analysis of variance (ANOVA) tests and/or nonparametric tests such as the Kruskal-Wallis test (block 312) depending on the types of data collected, assumptions regarding the statistical properties of underlying distributions, sampling schemes, and the like. In some examples, the first and second subsets of the relevant samples, regardless of whether the relevant samples are wafer lots or groups of wafer lots, may comprise non-intersecting subsets. In some examples, a first subset may comprise a first portion of a slot order sequence of a plurality of wafers, wherein the slot order sequence may identify a run sequence of the wafers in the process tool deployed at a targeted process step. In similar fashion, a second subset may comprise a second portion of the slot order sequence of the wafers, wherein the first and second portions are at respective ends of the run sequence. By way of illustration, at a frame level (e.g., where multiple wafer lots are loaded and processed in batches), a delta between a first average of the first [x] number of slots and a second average of the last [y] number of slots for each of a given number of lots may be determined with respect to one or more relevant inline response metric variables associated with a targeted process step or one or more EOL response metrics such as yield, wafer-level functional/electrical parametrics, etc. measured after the BEOL sequence of a process flow. In some arrangements, the first [x] number of slots and the last [y] number of slots may be the same, e.g., five slots, respectively, although different (sub)sampling schemes may be used in some additional and/or alternative arrangements. In another example scenario involving chamber-level analysis, e.g., where the deltas are determined and analyzed for variance within each chamber of a multi-chamber process tool that can process a plurality of wafers in each chamber, a delta may be obtained between the average of a first few wafers (e.g., first two wafers) and the average of a last few wafers (e.g., last two wafers) running through each chamber. Skilled artisans will accordingly recognize upon reference hereto that delta signal analyses at different levels of granularity may be performed with respect to various response metric variables in an example implementation based on applicable wafer or wafer lot sampling and subsampling schemes, which in turn may depend on how wafers are loaded and processed at various process stages using different types of tooling in a fabrication environment.

In some arrangements, respective first and second portions of run order sequences from which corresponding averages are determined for delta signal computations may be customizable, e.g., from process stage to process stage, from one response metric variable to another response metric variable, etc. In illustrative scenarios set forth above, respective first and second portions of run order sequences are selected or sampled from the two opposite ends or “tails” of the sequences in order to maximize or amplify any differences between the two extremal portions of the sequences, whereby “clean” differential signals (e.g., with low noise) may be obtained for further statistical analysis. For purposes of some examples of the present disclosure, such (sub)sampling of run order sequences may be termed “extremal (sub)sampling” or “end-tail (sub)sampling”, wherein a differential signal (e.g., the delta between the respective means or averages) corresponding to a response metric variable is operable as dependent random variable that may be tested for the null hypothesis of whether a transitional condition does not have a statistically significant impact on the variation of the differential signal at a given confidence level. As previously noted, nonparametric and/or parametric statistical techniques may be used in example implementations in identifying statistically significant transitional conditions. Additional details with respect to applying relevant statistical techniques in conjunction with delta signal analysis may be found in the U.S. Provisional Patent Application No. 63/433,807, referenced and incorporated hereinabove, to which the present patent application claims priority.

In some examples, responsive to identifying assignable transitional conditions that are determined to cause or contribute to the variability of the delta signals, appropriate response action plans may be generated, as set forth at block 314. In some examples, disposition analysis including wafer rework, adjusting process parameters for subsequent lots, (re)conditioning or (re)seasoning the tooling equipment, etc., may be executed, wherein at least some actions may involve automatic and/or manual control signaling provided to one or more process stages of the high mix manufacturing environment 302 as noted previously.

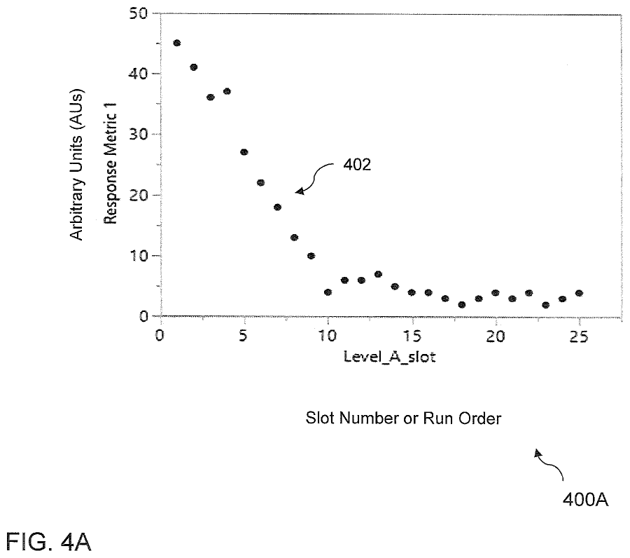

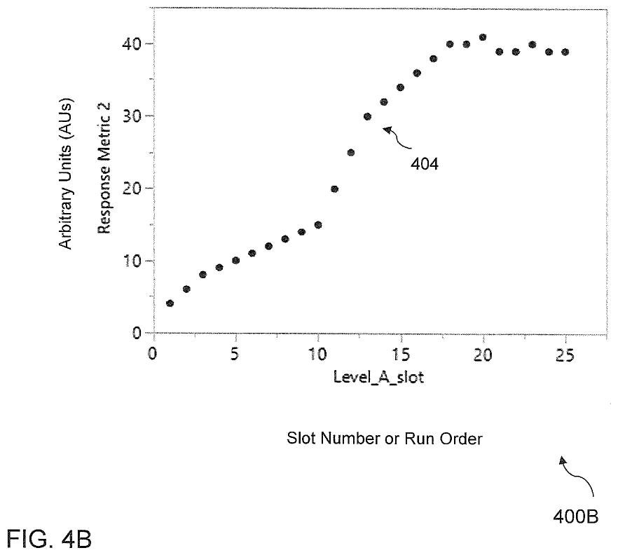

FIGS. 4A and 4B depict example response metrics relationships relative to a wafer slot or run order sequence at a targeted process step that may be undergoing a transitional condition. Reference number 400A in FIG. 4A refers to a graph wherein a wafer slot number or run order is plotted on X-axis whereas a response metric is plotted on Y-axis in arbitrary units (AUs), wherein a decreasing trend 402 is shown in the response metric values. In similar fashion, reference number 400B in FIG. 4B refers to a graph wherein an example response metric variable exhibits an increasing trend 404. In one arrangement, the response metric variable in graphs 400A/400B may comprise a variety of process measurement variables as noted previously, which may relate to, without limitation, one or more CDs, gate overlay alignment, gate length, layer thickness, layer planarization, etch profiles, particulate counts, defect categories and types, etc., as well as suitable electrical variables such as, e.g., sheet resistance, or other parametric electrical data, etc., that may depend on the material layer(s) of the wafers processed at a targeted process stage. Broadly, depending on the metrological instrumentation deployed in a fabrication environment, various physical, chemical, electrical, mechanical and kinetic properties or characteristics of material layers and other structures formed in or over appropriate semiconductor substrates may be used as inline response metrics. In another arrangement, the response metric variable may comprise an EOL metric, e.g., yield in DPW. In example implementations, several response metric variables may be monitored and plotted against the run order sequences for multiple inline stages as well as EOL stages in order to obtain a comprehensive analysis of the effects that various transitional conditionalities may have in the fabrication environment.

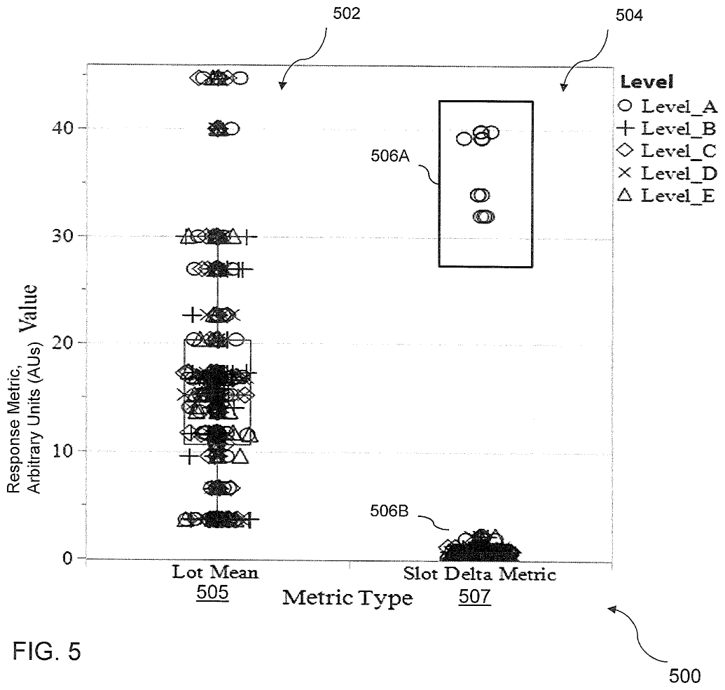

FIG. 5 depicts a slot delta metric relative to a response metric variable based on extremal (sub)sampling of wafer lots or process runs for isolating response metric variability due to transitional conditions according to some examples of the present disclosure. Reference number 500 refers to a graph wherein the averages of an example response metric variable for each wafer lot of a plurality of lots as well as the deltas between the averages of subsampled extremal portions of respective slot run order sequences are plotted against two categorical metrics: lot mean 505 and slot delta metric 507. Reference number 502 refers to a plot showing the averages of different lots at five different example process steps/stages or operations, abstractly referred to as Level-A to Level-E, whereas reference number 504 refers to a plot showing the deltas between the averages obtained for the extremal portions of the slot run order sequences. In each of these plots Level-A data is symbolically represented by O, Level-B data is symbolically represented by +, Level-C data is symbolically represented by ⋄, Level-D data is symbolically represented by ×, and Level-E data is symbolically represented by Δ. As can be seen in this Figure, the averages of the entire lots, e.g., lot mean data plot 502, obscure any indication that there might be a potential transitional conditionality affecting the data. On the other hand, the slot delta plot 504 separates a portion 506A of the data where the deltas associated with certain lots are more pronounced than the remaining deltas 506B, indicating at least a few impacted lots at one or more process operations due to a transitional conditionality. In some arrangements, a transition analysis engine may further execute appropriate statistical techniques in order to ascertain that one or more transitional conditionalities at one or more process operations (e.g., Level-A to Level-E) contribute to the variation in the slot delta values of the impacted lots in a statistically significant manner as set forth previously.

In some arrangements, an example transition analysis engine, e.g., engine 116 in FIG. 1 or engine 214 in FIG. 2, may be implemented based on a variety of scripting languages such as, without limitation, JavaScript, Python, Perl, Ruby, Lua, Bash, to name a few, although high-level computer languages may also be used in some additional and/or alternative examples. In some arrangements, a heatmap visualization engine may also be provided to facilitate a “dashboard” display that allows a graphical visualization of which particular combinations of response metrics, transition types, and process stages/levels exhibit statistically significant transition-based effects in the measured response metric variables.

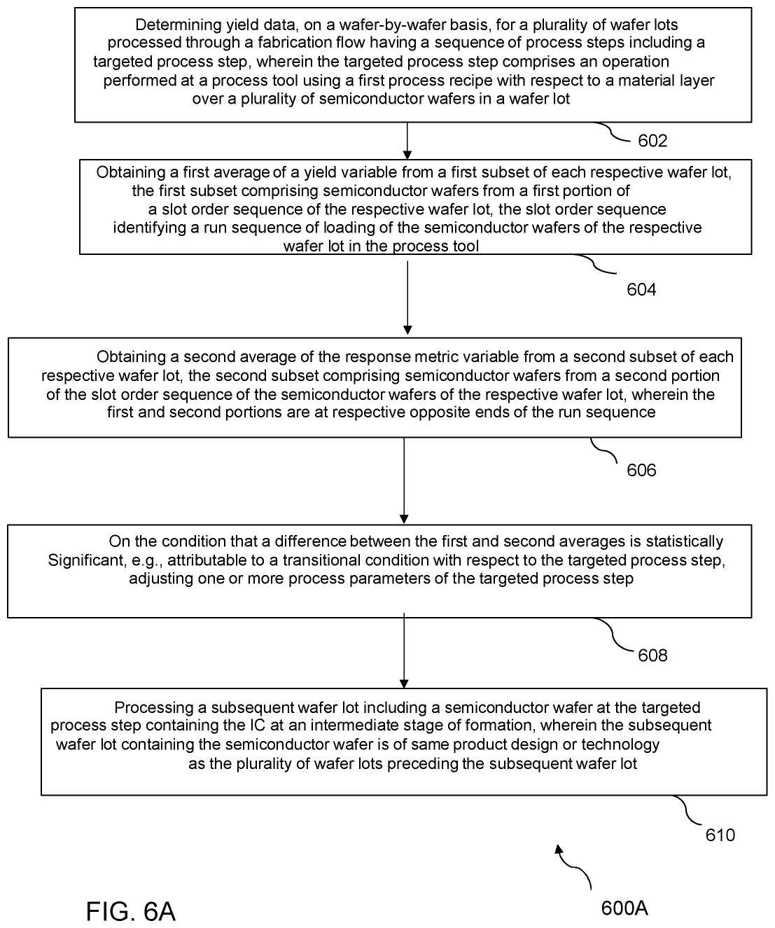

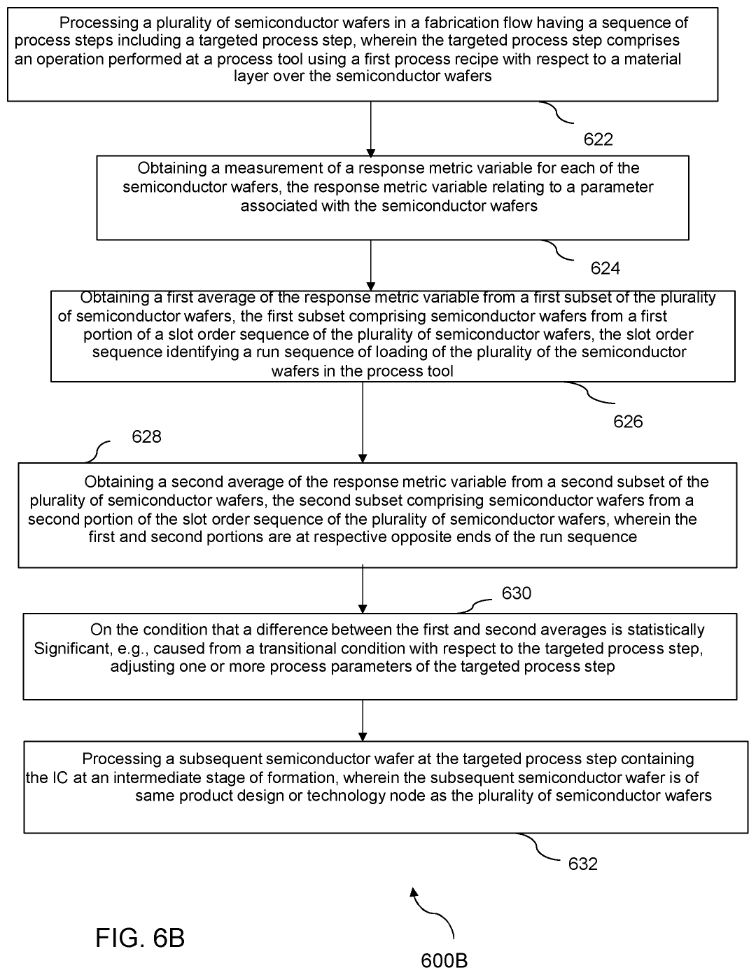

FIGS. 6A and 6B are flowcharts of an IC fabrication method according to some examples of the present disclosure. Method 600A may commence with determining yield data, e.g., on a wafer-by-wafer basis, for a plurality of wafer lots processed through a fabrication flow having a sequence of process steps including a targeted process step, wherein the targeted process step may comprise an operation performed at a process tool using a first process recipe with respect to a material layer over a plurality of semiconductor wafers in a wafer lot (block 602). At block 604, a first mean or average of a yield variable may be determined, calculated, or otherwise obtained from a first subset of each respective wafer lot. In some arrangements, the first subset may comprise semiconductor wafers from a first portion of a slot order sequence of the respective wafer lot, the slot order sequence identifying a run sequence of loading of the semiconductor wafers of the respective wafer lot in the process tool. Further, a second mean or average of the response metric variable may likewise be determined from a second subset of each respective wafer lot, wherein the second subset may comprise semiconductor wafers from a second portion of the slot order sequence of the semiconductor wafers of the respective wafer lot (block 606). In some arrangements, the first and second portions may be selected from respective opposite ends of the run sequence, and may or may not comprise equal sizes, as noted previously. On the condition that a difference between the first and second means or averages is statistically significant and, e.g., attributable to a transitional condition with respect to the targeted process step, one or more process parameters of the targeted process step may be adjusted (block 608). In some examples, method 600A may comprise processing a subsequent wafer lot including a semiconductor wafer at the targeted process step containing the IC at an intermediate stage of formation (block 610). In some examples, the subsequent wafer lot containing the semiconductor wafer having the IC device may be of same product design and/or technology node as the plurality of wafer lots preceding the subsequent wafer lot.

In some examples, the means from the respective first subsets of N wafer lots may also be averaged to obtain a first grand mean (e.g., a numerical average (mean) of a group of averages). Likewise, a second grand mean may be determined from the means of the respective second subsets selected from N wafer lots. Suitable parametric and/or nonparametric statistical techniques may be applied to determine whether the grand means are significantly different, similar to the statistical techniques set forth hereinabove. Nested/multifactorial as well as multivariate techniques may also be performed in some examples to determine whether there are statistically significant differences in the measured response metric variables at different levels of granularity, e.g., frame level, chamber level, or wafer level, that may be attributed to one or more transitional conditionalities in a manufacturing environment in addition to and/or in combination with other transitional conditionalities or other influencing factors.

Method 600B shown in FIG. 6B may involve processing a plurality of semiconductor wafers in a fabrication flow having a sequence of process steps including a targeted process step, wherein the targeted process step may comprise an operation performed at a process tool using a first process recipe with respect to a material layer over the semiconductor wafers (block 622). At block 624, a response metric variable may be measured, determined or otherwise obtained for each of the semiconductor wafers, wherein the response metric variable may relate to a parameter associated with the semiconductor wafers. At block 626, a first mean or average of the response metric variable may be determined, computed, or otherwise obtained from a first subset of the plurality of semiconductor wafers. Similar to the examples set forth above, the first subset may comprise a sampling of semiconductor wafers from a first portion of a slot order sequence of the plurality of semiconductor wafers, wherein the slot order sequence is operable to identify a run sequence of loading of the plurality of the semiconductor wafers in the process tool. Thereafter, a second mean or average of the response metric variable may likewise be determined with respect to a second subset of the plurality of semiconductor wafers, wherein the second subset may comprise a sampling of semiconductor wafers from a second portion of the slot order sequence of the plurality of semiconductor wafers. As noted previously, the first and second portions may be selected from respective opposite ends of the run sequence although it is not a requirement. Further, the first and second subsets may comprise non-overlapping or non-intersecting portions in some examples, as previously noted. Similar to some previous examples, method 600B may also comprise steps or acts relating to adjusting one or more process parameters of the targeted process step in response to determining that a difference between the first and second means or averages is statistically significant and caused from a transitional condition with respect to the targeted process step, as set forth at block 630. Further, method 600B may also include steps or acts relating to processing a subsequent semiconductor wafer at the targeted process step containing the IC at an intermediate stage of formation, wherein the subsequent semiconductor wafer is of same product design and/or technology node as the plurality of semiconductor wafers.

In addition to semiconductor fabrication, various disclosed methods and systems of the present disclosure may be beneficially applied to other manufacturing processes wherein various combinations of process flows may be continually configured on common tooling platforms in order to manufacture diverse products. Responsive to real-time action plan triggers and alarms, various factory-specific and industry-specific predetermined disposition mechanisms, etc., may be implemented in a configurable manner such that the effects of stochastic transitional events in a manufacturing environment can be isolated in accordance with some examples herein. Further, any deleterious effects of the transitions may be prophylactically prevented or other otherwise minimized before such effects can cause significant deviation in end-product quality, reliability, performance, etc.

One or more examples of the present disclosure may be implemented using different combinations of software, firmware, and/or hardware. Thus, one or more of the techniques shown in the Figures (e.g., flowcharts) may be implemented using code and data stored and executed on one or more electronic devices or nodes (e.g., a workstation, a network element, etc.). Such electronic devices may store and communicate (internally and/or with other electronic devices over a network) code and data using computer-readable media, such as non-transitory computer-readable storage media (e.g., magnetic disks, optical disks, random access memory, read-only memory, flash memory devices, phase-change memory, etc.), transitory computer-readable transmission media (e.g., electrical, optical, acoustical or other form of propagated signals—such as carrier waves, infrared signals, digital signals), etc. In addition, some network elements or workstations, e.g., configured as servers, may typically include a set of one or more processors coupled to one or more other components, such as one or more storage devices (e.g., non-transitory or persistent machine-readable storage media) as well as storage database(s), user input/output devices (e.g., a keyboard, a touch screen, a pointing device, one or more imaging capturing devices and/or a display, etc.), and network connections for effectuating signaling and/or data transmission. The coupling of the set of processors and other components may be typically through one or more buses and bridges (also termed as bus controllers), arranged in any known (e.g., symmetric/shared multiprocessing) or heretofore unknown architectures. Thus, the storage device or component of a given electronic device or network element may be configured to store program code and/or data for execution on one or more processors of that element, node or electronic device for purposes of implementing one or more techniques of the present disclosure.

At least some examples are described herein with reference to one or more system diagrams/schematics, block diagrams and/or flowchart illustrations. It is understood that such diagrams and/or flowchart illustrations, and combinations of blocks in the block diagrams and/or flowchart illustrations, can be implemented by any appropriate circuitry configured to achieve the desired functionalities. Accordingly, some examples of the present disclosure may be embodied in hardware and/or in software (including firmware, resident software, micro-code, etc.) operating in conjunction with suitable processing units or microcontrollers, which may collectively be referred to as “circuitry,” “a module” or variants thereof. An example processing unit or a module may include, by way of illustration, a general purpose processor, a special purpose processor, a conventional processor, a digital signal processor (DSP), an image processing engine or unit, a plurality of microprocessors, one or more microprocessors in association with a DSP core, a controller, a microcontroller, Application Specific Integrated Circuits (ASICs), Field Programmable Gate Array (FPGA) circuits, any other type of integrated circuit (IC), and/or a state machine, as well as programmable system devices (PSDs) employing system-on-chip (SoC) architectures that combine memory functions with programmable logic on a chip that is designed to work with a standard microcontroller. Example memory modules or storage circuitry may include volatile and/or non-volatile memories such as, e.g., random access memory (RAM), electrically erasable/programmable read-only memories (EEPROMs) or UV-EPROMS, one-time programmable (OTP) memories, Flash memories, static RAM (SRAM), etc.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. A method of fabricating an integrated circuit (IC), the method comprising:
processing a plurality of semiconductor wafers in a fabrication flow having a sequence of process steps including a targeted process step, wherein the targeted process step comprises an operation performed at a process tool using a first process recipe with respect to a material layer over the semiconductor wafers;
obtaining a measurement of a response metric variable for the semiconductor wafers, the response metric variable relating to a parameter associated with the semiconductor wafers;
obtaining a first average of the response metric variable from a first subset of the plurality of semiconductor wafers;
obtaining a second average of the response metric variable from a second subset of the plurality of semiconductor wafers;
on the condition that a difference between the first and second averages is statistically significant, adjusting one or more process parameters of the targeted process step; and
processing a subsequent semiconductor wafer at the targeted process step containing the IC at an intermediate stage of formation, wherein the subsequent semiconductor wafer is of a same technology node as the plurality of semiconductor wafers.

2. The method as recited in claim 1, wherein the first subset and the second subset are non-intersecting subsets.

3. The method as recited in claim 1, wherein:
the first subset comprises semiconductor wafers from a first portion of a slot order sequence of the plurality of semiconductor wafers, the slot order sequence identifying a run sequence of loading of the plurality of the semiconductor wafers in the process tool; and
the second subset comprises semiconductor wafers from a second portion of the slot order sequence of the plurality of semiconductor wafers, wherein the first and second portions are at respective opposite ends of the run sequence.

4. The method as recited in claim 3, wherein the first portion of the slot order sequence comprises first five slots of a wafer lot comprising the plurality of semiconductor wafers.

5. The method as recited in claim 3, wherein the second portion of the slot order sequence comprises last five slots of a wafer lot comprising the plurality of semiconductor wafers.

6. The method as recited in claim 1, wherein the first and second subsets are of different size.

7. The method as recited in claim 1, wherein the transitional condition comprises a process recipe transition relative to changing a process recipe to the first process recipe for processing the targeted process step.

8. The method as recited in claim 1, wherein the transitional condition comprises a product design transition relative to changing from one IC design to another IC design at the process tool for processing the plurality of semiconductor wafers at the targeted processing step.

9. The method as recited in claim 1, wherein the transitional condition comprises a technology node transition relative to changing from one technology node to another technology node at the process tool for processing the plurality of semiconductor wafers at the targeted processing step.

10. The method as recited in claim 1, wherein the transitional condition comprises a state transition relative to the process tool deployed to perform the targeted process step.

11. The method as recited in claim 1, wherein the response metric variable comprises a yield variable, a quality parametric variable, a critical dimension (CD) variable, an overlay alignment variable, a layer thickness variable, a layer planarization variable, an etch profile variable, a defect count variable, and an electrical parametric variable.

12. A method of fabricating an integrated circuit (IC), the method comprising:
determining yield data, on a wafer-by-wafer basis, for a plurality of wafer lots processed through a fabrication flow having a sequence of process steps including a targeted process step, wherein the targeted process step comprises an operation performed at a process tool using a first process recipe with respect to a material layer over a plurality of semiconductor wafers in a wafer lot;
obtaining a first average of a yield variable from a first subset of each respective wafer lot;
obtaining a second average of the yield variable from a second subset of each respective wafer lot;
on the condition that a difference between the first and second averages is statistically significant, adjusting one or more process parameters of the targeted process step; and
processing a subsequent wafer lot including a semiconductor wafer at the targeted process step containing the IC at an intermediate stage of formation, wherein the subsequent wafer lot containing the semiconductor wafer is of a same technology node as the plurality of wafer lots immediately preceding the subsequent wafer lot.

13. The method as recited in claim 12, wherein the first subset and the second subset of a respective wafer lot are non-intersecting subsets.

14. The method as recited in claim 12, wherein:
the first subset comprises semiconductor wafers from a first portion of a slot order sequence of a respective wafer lot, the slot order sequence identifying a run sequence of loading of the semiconductor wafers of the respective wafer lot in the process tool; and
the second subset comprises semiconductor wafers from a second portion of the slot order sequence of the semiconductor wafers of the respective wafer lot, wherein the first and second portions are at respective opposite ends of the run sequence.

15. The method as recited in claim 14, wherein the first portion of the slot order sequence comprises first five slots of the respective wafer lot.

16. The method as recited in claim 14, wherein the second portion of the slot order sequence comprises last five slots of the respective wafer lot.

17. The method as recited in claim 12, wherein the first and second subsets of a respective wafer lot are of different size.

18. The method as recited in claim 12, wherein the transitional condition comprises a process recipe transition relative to changing a process recipe to the first process recipe for processing the plurality of wafer lots at the targeted process step.

19. The method as recited in claim 12, wherein the transitional condition comprises a product design transition relative to changing from one IC design to another IC design at the process tool for processing the plurality of wafer lots at the targeted processing step.

20. The method as recited in claim 12, wherein the transitional condition comprises a technology node transition relative to changing from one technology node to another technology node at the process tool for processing the plurality of wafer lots at the targeted processing step.

21. The method as recited in claim 12, wherein the transitional condition comprises a state transition relative to the process tool deployed to perform the targeted process step.

22. An integrated circuit (IC), comprising:
a material layer formed over a semiconductor wafer at a targeted process step of a fabrication flow, the semiconductor wafer forming a substrate for the IC; and
the material layer reworked responsive to determining that a difference between a first average of a response metric variable and a second average of the response metric variable are statistically significant and attributable to a transitional condition with respect to the targeted process step performed by a process tool using a first process recipe.
